(19) United States
(12) Patent Application Publication
(10) Pub. No.: US 2006/0262503 A1
(43) Pub. Date: Nov. 23, 2006

(54) Cooling system for a substrate

(76) Inventors: Matthew G. Bevan, Silver Spring, MD (US); Keith J. Rebello, Columbia, MD (US); Alan Adams, Chambersburg, PA (US); Rafal P. Szczepanowski, Hanover, MD (US)

Correspondence Address: THE JOHNS HOPKINS UNIVERSITYAPPLIED PHYSICS LABORA;OFFICE OF PATENT COUNSEL, 11100 JOHNS HOPKINS ROAD, MAIL STOP 7-156, LAUREL, MD, 20723-6099, US

(21) Appl. No.: 11/315,792

(22) Filed: Dec. 22, 2005

Related U.S. Application Data
(60) Provisional application No. 60/638,349, filed on Dec. 22, 2004.

(51) Int. Cl. H05K 7/20

(52) U.S. Cl. 361/699

(57) ABSTRACT

The present invention relates to a cooling system, the cooling system having a nozzle which receives coolant from a reservoir and which faces a substrate. The nozzle may be opened and closed by a thermally responsive valve allowing the coolant to be automatically metered to the substrate, thus controlling the spatial distribution of the coolant that is applied to the substrate. This approach allows hotter areas of the substrate to receive more coolant, thus eliminating nonuniformities in the thermal profile of the substrate.

### BACKGROUND OF THE INVENTION

1. Field of the Invention

The present invention relates to a cooling system. More specifically, it relates to a cooling system which automatically meters the coolant that is applied to a substrate, based on ambient air or substrate temperature.

2. Description of the Related Art

Electronic systems are being manufactured with increasingly compact geometries. In a variety of applications such as telecommunications, cellular base stations and mobile phones, automotive electronics, aerospace, power distribution systems in computers, large-scale servers, military electronics and avionics, and many others, there is a need to remove heat from compact spaces. The space and performance constraints call for sophisticated cooling techniques which are easy to implement. In many applications, the absence of compact cooling techniques has jeopardized the viability of the product. Proper use of cooling technologies can also lead to important gains in efficiency and performance.

A typical approach to dissipate heat is through the use of heat pipes. Heat pipes can offer significantly better heat conduction than solid metal rods of the same dimensions, and are widely used in many applications.

Heat pipes consist of a hollow tube which incorporates a wicking structure, and is partially filled with liquid. One end of the heat pipe is placed in contact with the heat-generating device. At this end of the heat pipe, the liquid evaporates, and vapor travels down the hollow center of the pipe to the other end. This end is placed into contact with a cold medium, or a heat sink, or is in contact with the surrounding air, and acts to cool the vapor in the center of the tube to the condensation temperature. This liquid, after condensation, is transported back to the hot end of the tube by capillary forces within the wicking structure.

Many common designs include a substrate, often porous, which is either in close proximity to, or in direct contact with, the heat pipe. These designs often use a cooling system to disperse coolant into the substrate. To accomplish this, either the average substrate temperature or the power consumption is monitored. When the average substrate temperature is low or little power is being consumed, the pressure of the coolant fluid in the plenum drops to a minimum. As the power and temperature increase, the plenum pressure also increases. This increase in pressure also increases the flow of fluid into the substrate, thus balancing the increase in cooling requirements. If the substrate is composed of a porous media, the coolant may then spread throughout the porous media via capillary action.

Variations on this general design include the use of nozzles or similar devices which disperse the coolant into the substrate.

While these cooling devices achieve an average level of control of the system temperature, they suffer from a number of drawbacks. Typically, the heat load is not evenly distributed across the surface of the substrate, resulting in uneven temperature distribution on the surface areas. By only monitoring the average temperature, these devices do not compensate for such non-uniform temperatures across the substrate. This situation can result at best in inefficient use of coolant, and at worst in damage to the delicate electronics.

In order to overcome these problems, what is needed is a cooling system, which controls the spatial distribution of coolant by automatically directing more coolant to hotter areas. Thus, spatial nonunifomities in temperature are reduced. Further, this design allows use of numerous nozzles, distributed above the substrate to spray only the substrates hot areas. This simplifies the design of the associated coolant plenum and pressures of the associated pump, thus addressing and solving problems associated with conventional systems.

### SUMMARY OF THE INVENTION

The present invention relates to a cooling system, the cooling system having a nozzle which receives coolant from a reservoir and which faces the substrate. The nozzle may be opened and closed by a thermally actuated valve allowing the coolant to be automatically metered to the substrate, thus controlling the coolant that is applied to the substrate. By using multiple nozzles, this approach allows hotter areas to receive more coolant than cooler areas of the substrate, thus eliminating nonuniformities in the thermal profile of the substrate without adding excessive fluid which may reduce performance.

It is an object of the invention disclosed herein to provide a new and improved cooling system, which provides novel utility through the use of a unique design which allows hotter areas of the substrate to receive more coolant than low temperature areas, thus achieving more uniform cooling of the substrate.

It is another object of the invention disclosed herein to provide a new and improved cooling system, which allows hotter areas of the substrate to receive more coolant than cooler areas, thus causing a greater fraction of the coolant to be evaporated, thereby improving the performance and efficiency of the system.

It is an advantage of the invention disclosed herein to provide a new and improved cooling system, which can operate with lower coolant pressures, thus simplifying the design of the coolant plenum and pressures of the associated pump.

It is an advantage of the invention disclosed herein to control the flow of coolant and permit spraying nozzles from using excessive fluid.

These and other objects and advantages of the present invention will be fully apparent from the following description, when taken in connection with the annexed drawings.

### BRIEF DESCRIPTION OF THE DRAWINGS

The teachings of the present invention can be readily understood by considering the following detailed description in conjunction with the accompanying drawings, in which:

FIG. 1 is a cross-sectional view of an example of a first embodiment according to the principles of the present application, of a cooling system in an open state;

FIG. 2 is a cross-sectional view of an example of a first embodiment according to the principles of the present application, of a cooling system in a closed state;

FIG. 3 is a cross-sectional view of an example of a second embodiment according to the principles of the present application, of a cooling system in an open state;

FIG. 4 is a cross-sectional view of an example of a second embodiment according to the principles of the present application, of a cooling system in a closed state.

### DETAILED DESCRIPTION OF EXEMPLARY EMBODIMENTS

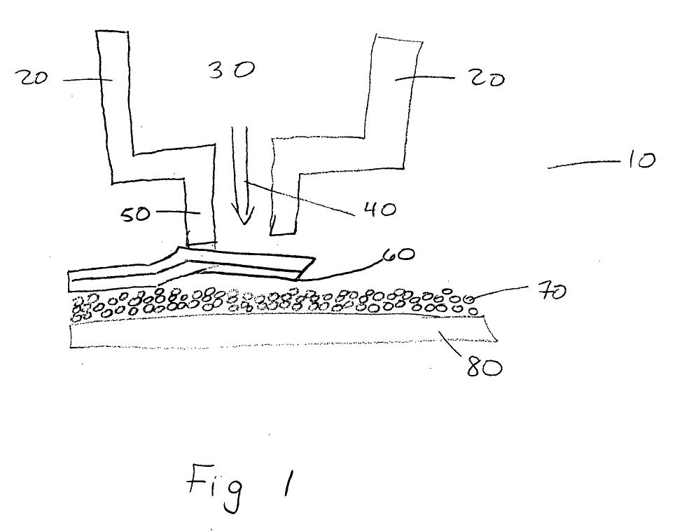

Referring now to the drawings in greater detail, FIG. 1 shows a cross-sectional view of a first embodiment according to the principles of the present application. Cooling system 10 includes housing 20 having a substantially hollow tubular shape. Housing 20 is open at the upper end and substantially closed at the lower end. The hollow shape of housing 20 defines coolant plenum 30. Note that the principles of the present application may be applied to a wide variety of plenum designs, hence the specific design of plenum 30 shown in FIG. 1 is not intended to limit the scope of this application.

The lower end of plenum 30 has an opening 40 which allows coolant to flow into nozzle 50. Nozzle 50 has a hollow tubular shape. Coolant flows into nozzle 50 through opening 40 in plenum 30.

Nozzle 50 is in communication with thermally responsive valve 60. FIG. 1 illustrates valve 60 mounted onto substrate 70, and substrate 70 contacting heat source 80. In this embodiment, valve 60 responds to changes in the temperature of substrate 70.

Furthermore, FIG. 1 illustrates valve 60 in an open state. Such an open state results from the temperature of substrate 70 increasing and thereby causing the temperature of valve 60 to increase beyond a predetermined value. In this open state, valve 60 does not obstruct the flow of coolant and thus coolant from plenum 30 flows through nozzle 50 and continues flowing through valve 60 onto substrate 70. In this fashion, coolant flow is tuned to be distributed to the area of substrate 70 of greatest need.

One type of thermally responsive valve 60 may be a bimetallic strip. Note that the principles of the present application may be applied to a variety of thermally responsive valves 60, hence neither the specific design of thermally responsive valve 60 shown in FIG. 1, nor the use of bimetallic strips or nitinol as one type of such valve, are intended to limit the scope of this application.

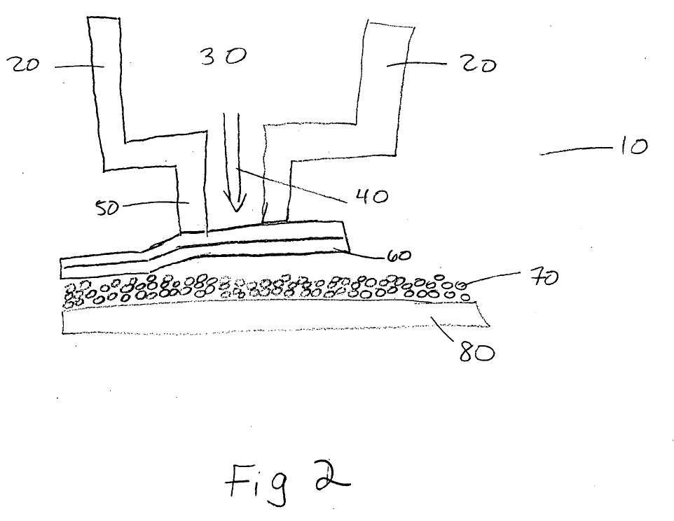

FIG. 2 illustrates the first embodiment in a closed state. In this illustration, the temperature of substrate 70 is within a predetermined normal operating range, and thus thermally responsive valve 60 is closed in response to the temperature of substrate 70. Valve 60 is thus obstructing the flow of coolant, so that coolant is not flowing into substrate 70.

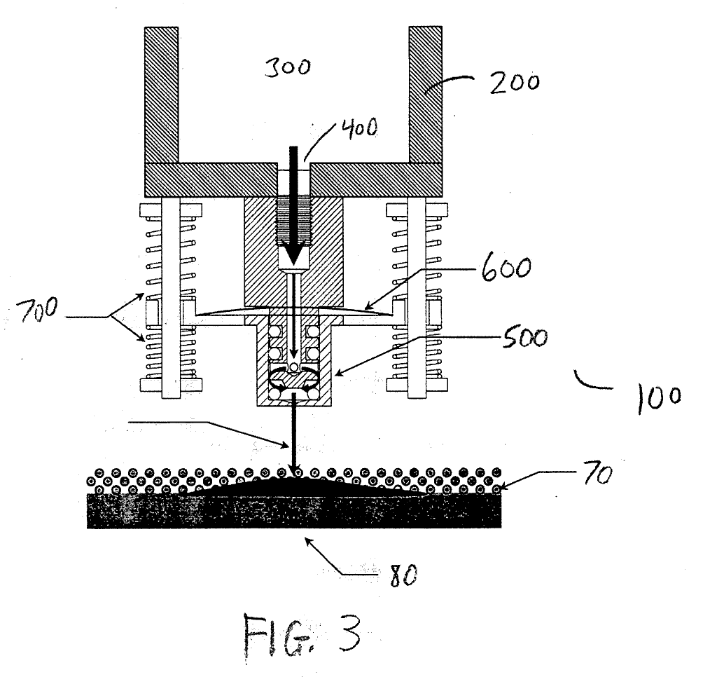

FIG. 3 illustrates an example of a second embodiment according to the principles of the present application. Cooling system 100 includes housing 200 having a substantially hollow tubular shape. Housing 200 is open at the upper end and substantially closed at the lower end. The hollow shape of housing 200 defines coolant plenum 300. Coolant plenum 300 is under pressure. Note that the principles of the present application may be applied to a wide variety of plenum designs, hence the specific design of plenum 300 shown in FIG. 3 is not intended to limit the scope of this application.

The lower end of plenum 300 has an opening 400 which allows coolant to flow into nozzle 500. Nozzle 500 has a hollow tubular shape. Coolant flows into nozzle 500 through opening 400 in plenum 300.

Nozzle 500 is in communication with thermally responsive valve 600. FIG. 3 illustrates thermally responsive valve 600 mounted onto nozzle 500. In this second embodiment, valve 600 is not mounted on substrate 700. Being attached to nozzle 500, valve 600 responds to changes in ambient temperature. FIG. 3 illustrates valve 600 in an open state. When the ambient temperature increases beyond a predetermined level, valve 600 opens, no longer obstructing the flow of coolant, and thus allows coolant from plenum 300 to flow throughout the full length of nozzle 500 onto substrate 70. In this fashion, coolant flow can be tuned to be distributed to the area of substrate 70 of greatest need.

One type of thermally responsive valve 60 may be a bimetallic strip. Note that the principles of the present application may be applied to a variety of thermally responsive valves 60, hence neither the specific design of valve 60 shown in FIG. 3, nor the use of bimetallic strips as one type of such valve, are intended to limit the scope of this application.

Also illustrated in FIG. 3 are counterbalancing springs 700 which are shown mounted to the plenum housing 200 and which attach to valve 600. Counterbalancing springs 700 accomplish the dual purposes of providing compensation for coolant pressure and also providing adjustable spring tension against valve 600.

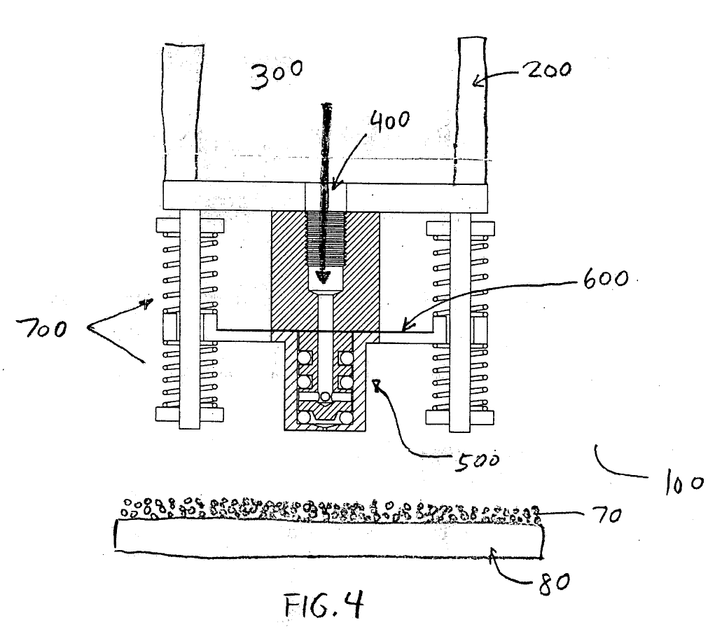

FIG. 4 illustrates the second embodiment in a closed state. In this illustration, the ambient temperature of thermally responsive valve 600 is within a predetermined normal operating range, and thus thermally responsive valve 600 is closed in response thereto and obstructs the flow of coolant. Therefore, coolant is not flowing into substrate 70.

In operation, in the first embodiment of the invention, heat source 80 causes the temperature of substrate 70 to increase. As the temperature of substrate 70 increases and reaches a predetermined range, thermally responsive valve 60 mounted on the substrate 70 opens, allowing coolant to flow through nozzle 50 onto substrate 70.

In second embodiment of the invention, a heat source 80 may cause the temperature of substrate 70 to increase. As the temperature of substrate 70 increases, ambient temperature and potentially fluid vapor temperature surrounding thermally responsive valve 600 increases, thus heating valve 600. When valve 600 reaches a predetermined temperature, valve 600 may open, allowing coolant to flow throughout the full length of nozzle 500 and onto substrate 70. In one embodiment, the valve 600 may also be connected to the substrate 70 via a heat finger or other device. This may allow the valve 600 to actuate based on changes in substrate temperature.

It should be apparent to those skilled in the art that the present invention may be embodied in many other specific forms without departing from the spirit or scope of the invention. Therefore, the present examples and embodiments are to be considered as illustrative and not restrictive, and the invention is not to be limited to the details given herein, but may be modified within the scope of the appended claims.

What is claimed is:

1. A coolant control apparatus for use in combination with a cooling device, which cooling device includes
a substrate, a predetermined region of a lower surface of which contacts a heat source;
a coolant plenum;
a nozzle having a coolant inlet, said coolant inlet being in communication with said coolant plenum;
means for mounting said nozzle so that said nozzle is in facing relation to said substrate, and whereby said coolant discharged from said nozzle intersects said substrate;
said coolant control apparatus comprising:
a thermally responsive valve, said valve having a first end and a second end, said first end in communication with said nozzle and said second end being mounted on said substrate;
whereby said thermally responsive valve opens in response to the substrate temperature reaching a predetermined range, and thus causing coolant to flow into said substrate.

2. The device of claim 1, wherein said thermally responsive valve is a bimetallic valve.

3. A coolant control apparatus for use in combination with a cooling device, which cooling device includes
a substrate, a predetermined region of a lower surface of which contacts a heat source;
a coolant plenum;
a nozzle having a coolant inlet, said coolant inlet being in communication with said coolant plenum;
means for mounting said nozzle so that said nozzle is in facing relation to said substrate, and whereby said coolant discharged from said nozzle intersects said substrate;
said coolant control apparatus comprising:
a thermally responsive valve, said valve being mounted on said nozzle; and
whereby said thermally responsive valve opens in response to the ambient temperature reaching a predetermined range, and thus allowing coolant to flow into said substrate.

4. The device of claim 3, wherein said thermally responsive valve is a bimetallic valve.

5. The apparatus of claim 4, further comprising a means for adjusting the amount of tension in the bimetallic valve required to open said nozzle.

6. The apparatus of claim 5, wherein said means for adjusting the amount of tension in the bimetal valve is a counterbalance spring.

7. A method for controlling coolant flow for use in combination with a cooling device, which cooling device includes
a substrate, a predetermined region of a lower surface of which contacts a heat source;
a coolant plenum;
a nozzle having a coolant inlet, said coolant inlet being in communication with said coolant plenum;
means for mounting said nozzle so that said nozzle is in facing relation to said substrate, and whereby said coolant discharged from said nozzle intersects said substrate;
said method comprising:
providing a thermally responsive valve, said valve having a first end and a second end;
placing said first end in communication with said nozzle and mounting said second end on said substrate; whereby said thermally responsive valve opens in response to the substrate temperature reaching a predetermined range, and thus allows coolant to flow into said substrate.

8. The method of claim 7, wherein said thermally responsive valve is a bimetallic valve.

9. A method for controlling coolant for use in combination with a cooling device, which cooling device includes:
a substrate, a predetermined region of a lower surface of which contacts a heat source;
a coolant plenum;
a nozzle having a coolant inlet, said coolant inlet being in communication with said coolant plenum;
means for mounting said nozzle so that said nozzle is in facing relation to said substrate, and whereby said coolant discharged from said nozzle intersects said substrate;
said method comprising:
providing a thermally responsive valve, said valve having a first end and a second end;
placing said first end in communication with said nozzle and mounting said second end on said substrate; whereby said thermally responsive valve opens in response to the substrate temperature reaching a predetermined range, and thus allows coolant to flow into said substrate.

10. The method of claim 9, wherein said thermally responsive valve is a bimetallic valve.

11. A coolant control method for use in combination with a cooling device, which cooling device includes
a substrate, a predetermined region of a lower surface of which contacts a heat source;
a coolant plenum;
a nozzle having a coolant inlet, said coolant inlet being in communication with said coolant plenum;
means for mounting said nozzle so that said nozzle is in facing relation to said substrate, and whereby said coolant discharged from said nozzle intersects said substrate;
said method comprising:
providing a thermally responsive valve, and mounting said valve on said nozzle;
whereby said thermally responsive valve opens in response to the ambient temperature reaching a predetermined range, and thus allows coolant to flow into said substrate.

12. The method of claim 11, wherein said thermally responsive valve is a bimetallic valve.

13. The method of claim 12, further providing a means for adjusting the amount of tension in the bimetallic valve required to open said nozzle.

14. The method of claim 13, wherein said means for adjusting the amount of tension in the bimetal valve is a counterbalance spring.
